(19) United States
(12) Patent Application Publication
(10) Pub. No.: US 2012/0038033 A1
(43) Pub. Date: Feb. 16, 2012

(54) SEMICONDUCTOR DEVICE

(75) Inventors: Akira OGA, Shiga (JP); Yoshihiro Tomita, Osaka (JP); Masanori Minamio, Osaka (JP)

(73) Assignee: PANASONIC CORPORATION, Osaka (JP)

(21) Appl. No.: 13/285,896

(22) Filed: Oct. 31, 2011

Related U.S. Application Data
(63) Continuation of application No. PCT/JP2011/001735, filed on Mar. 24, 2011.

(30) Foreign Application Priority Data
Jul. 22, 2010 (JP) 2010-164558

(51) Int. Cl. H01L 23/495

(52) U.S. Cl. 257/659; 257/E23.052

(57) ABSTRACT

A semiconductor device includes a first semiconductor chip 1, a second semiconductor chip 4, a first lead frame 3 including a first die pad 9 on which the first semiconductor chip 1 is mounted, and a second lead frame 5 including a second die pad 11 on which the second semiconductor chip 4 is mounted. A sealing structure 6 covers the first semiconductor chip 1 and the second semiconductor chip 4. A noise shield 7 is disposed between the first semiconductor chip 1 and the second semiconductor chip 4.

### CROSS-REFERENCE TO RELATED APPLICATION

This is a continuation of PCT International Application PCT/JP2011/001735 filed on Mar. 24, 2011, which claims priority to Japanese Patent Application No. 2010-164558 filed on Jul. 22, 2010. The disclosures of these applications including the specifications, the drawings, and the claims are hereby incorporated by reference in their entirety.

### BACKGROUND

The present disclosure relates to semiconductor devices, and a method for manufacturing the same.

Further downsizing and weight reduction of inverter control devices have been required, and accordingly, downsizing and weight reduction of semiconductor devices such as power modules etc. included in the inverter control devices have also been required.

For the downsizing and weight reduction of the power modules, three dimensionally arranging a first lead frame including a power device, and a second lead frame including a control device for controlling the power device has been taken into account (see, e.g., Japanese Patent Publication No. 2005-150595). The downsizing and weight reduction are expected by sealing the three dimensionally arranged power device and control device in a resin package.

### SUMMARY

However, the conventional semiconductor device may disadvantageously reduce operational reliability. The power device performs switching at high frequency and large current, and tends to generate large electromagnetic wave noise. The electromagnetic wave noise affects the control device, and causes malfunction, thereby reducing the operational reliability.

When the semiconductor device is further downsized in the future, a distance between the power device and the control device is further reduced. This may leads to serious malfunction of the control device due to the electromagnetic wave noise.

The present disclosure is concerned with providing a semiconductor device with improved operational reliability.

Specifically, the disclosed semiconductor device includes: a first lead frame including a first die pad; a second lead frame including a second die pad; a first semiconductor chip disposed on the first die pad; a second semiconductor chip disposed on the second die pad; a sealing structure which covers the first semiconductor chip and the second semiconductor chip; and a noise shield disposed between the first semiconductor chip and the second semiconductor chip.

A method for manufacturing the disclosed semiconductor device includes: preparing a first lead frame including a first die pad on which a first semiconductor chip is mounted, and a heat sink fixed to a surface of the first die pad opposite the first semiconductor chip with an insulating sheet interposed therebetween, and a second lead frame including a second die pad on which a second semiconductor chip is mounted; placing the first lead frame and the second lead frame at predetermined positions in a lower mold, respectively; arranging an upper mold having a plurality of insert pins on the lower mold in such a manner that each of the insert pins is in contact with a surface of the first lead frame on which the first semiconductor chip is mounted; injecting a resin between the upper mold and the lower mold to form a package which covers the first semiconductor chip and the second semiconductor chip, and has a plurality of openings corresponding to the insert pins; and forming noise shielding poles constituting a noise shield in the openings, respectively, wherein the noise shield is formed between the first semiconductor chip and the second semiconductor chip.

In the disclosed method, the noise shielding poles may be arranged to form a barrier between the first semiconductor chip and the second semiconductor chip in the forming.

The disclosed method may further include fixing an electromagnetic wave absorber plate to a surface of the package on which the noise shield is formed after the forming.

In the disclosed method, a circuit board on which the first semiconductor chip is mounted may be fixed to the first die pad.

In the disclosed method, the first semiconductor chip may be a power semiconductor device, and the second semiconductor chip may be a control device.

The disclosed semiconductor device and the disclosed method for manufacturing the semiconductor device can provide semiconductor devices with improved operational reliability.

### BRIEF DESCRIPTION OF THE DRAWINGS

FIG. 1 is a plan view illustrating a semiconductor device according to a first embodiment.

FIG. 2 is a bottom view illustrating the semiconductor device according to the first embodiment.

FIGS. 3A-3D are plan views illustrating an inner structure of the semiconductor device according to the first embodiment.

FIGS. 4A-4D are cross-sectional views taken along the lines IVA-IVA, IVB-IVB, IVC-IVC, and IVD-IVD in FIGS. 3A-3D, respectively.

FIG. 5 is a plan view illustrating an alternative of the inner structure of the semiconductor device according to the first embodiment.

FIG. 6 is a cross-sectional view taken along the line VI-VI in FIG. 5.

FIG. 7 is a cross-sectional view illustrating a step of a method for manufacturing the semiconductor device according to the first embodiment.

FIG. 8 is a cross-sectional view illustrating a step of the method for manufacturing the semiconductor device according to the first embodiment.

FIG. 9 is a cross-sectional view illustrating a step of the method for manufacturing the semiconductor device according to the first embodiment.

FIG. 10 is a cross-sectional view illustrating a step of the method for manufacturing the semiconductor device according to the first embodiment.

FIG. 11 is a cross-sectional view illustrating a step of the method for manufacturing the semiconductor device according to the first embodiment.

FIG. 12 is a plan view illustrating a semiconductor device according to a second embodiment.

FIG. 13 is a plan view illustrating an inner structure of a semiconductor device according to a third embodiment.

FIG. 14 is a cross-sectional view taken along the line XIV-XIV in FIG. 13.

FIG. 15 is a cross-sectional view illustrating a semiconductor device according to a fourth embodiment.

FIG. 16 is a cross-sectional view illustrating an alternative of the semiconductor device according to the fourth embodiment.

### DETAILED DESCRIPTION

Embodiments of the present disclosure will be described below with reference to the drawings. The present disclosure is not limited to the following description unless otherwise deviated from the scope of the disclosure.

### First Embodiment

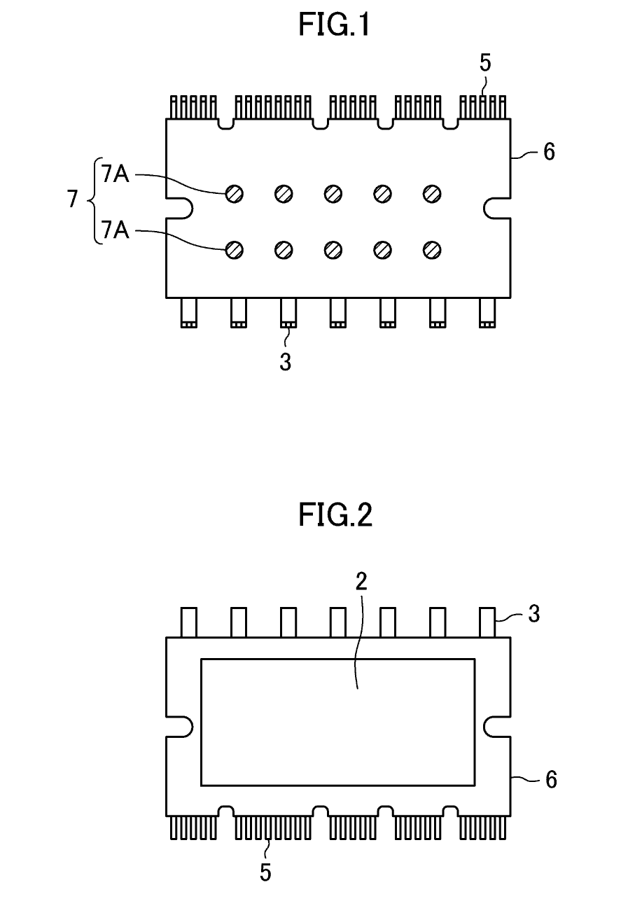

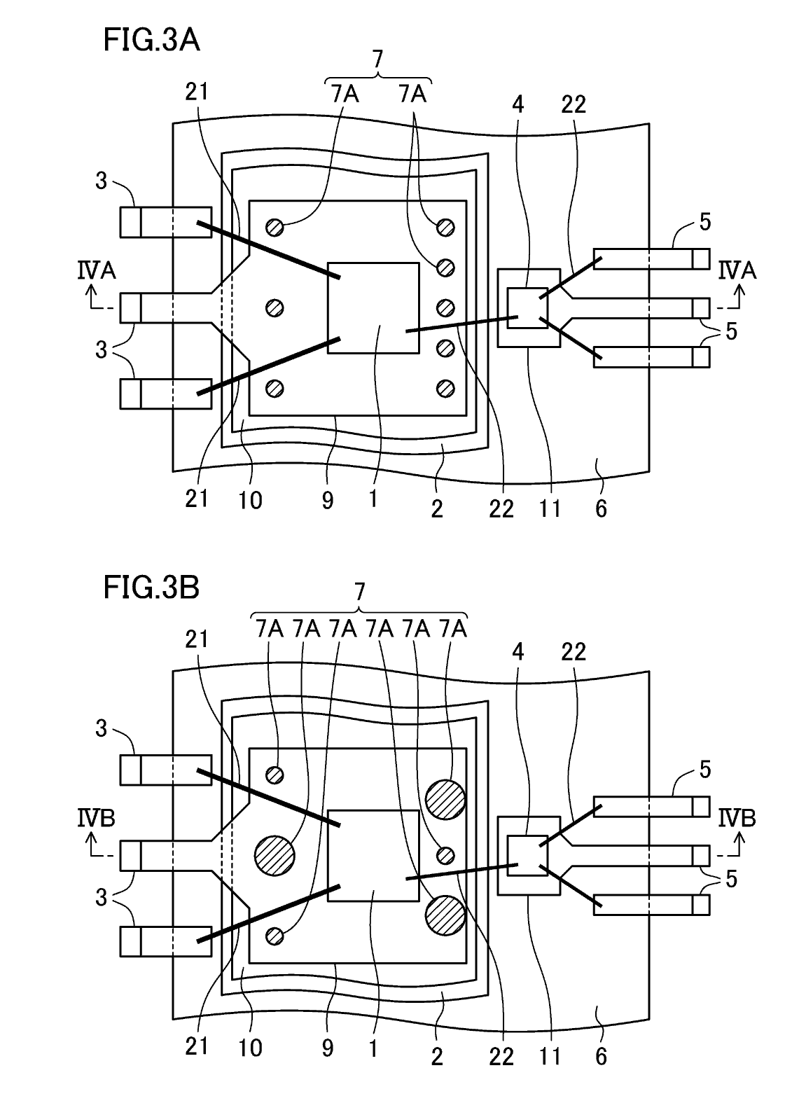

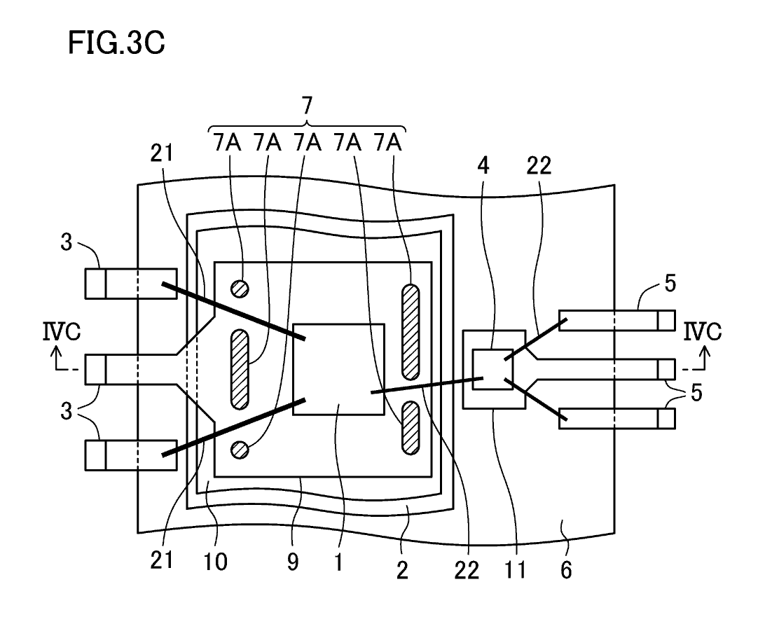

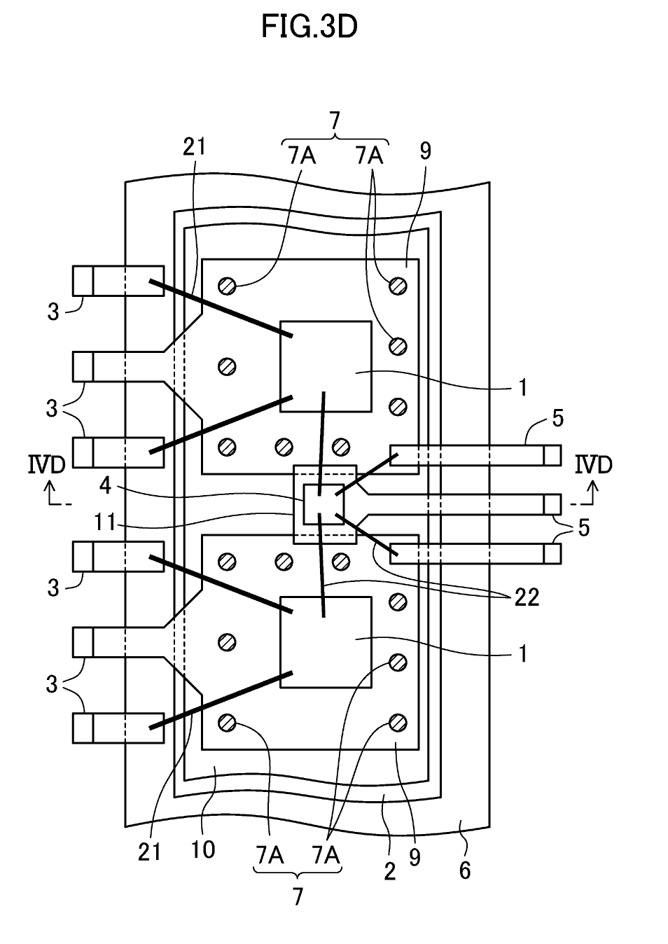

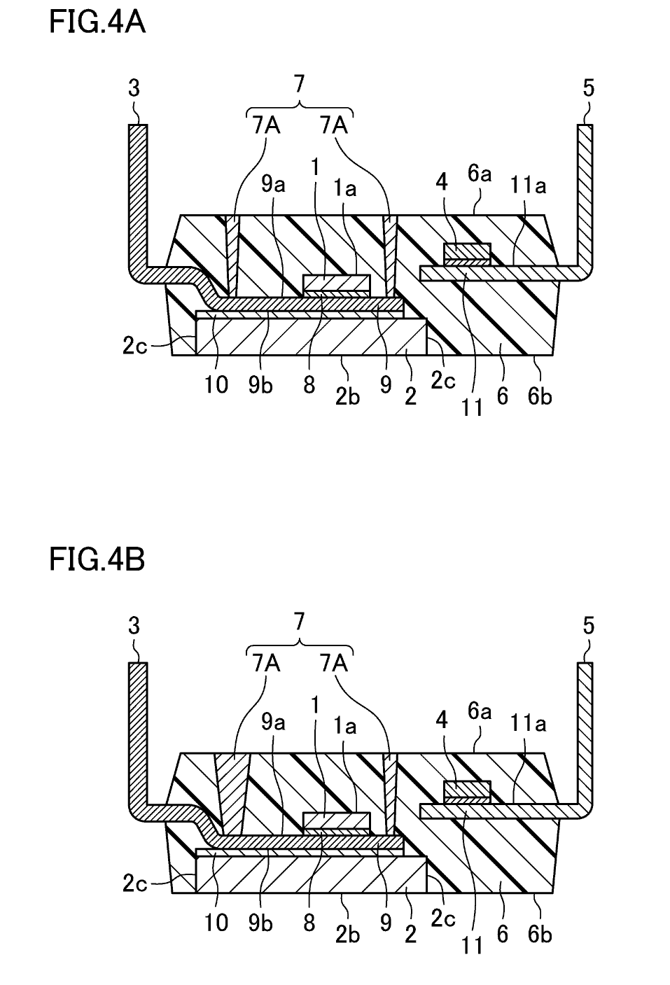

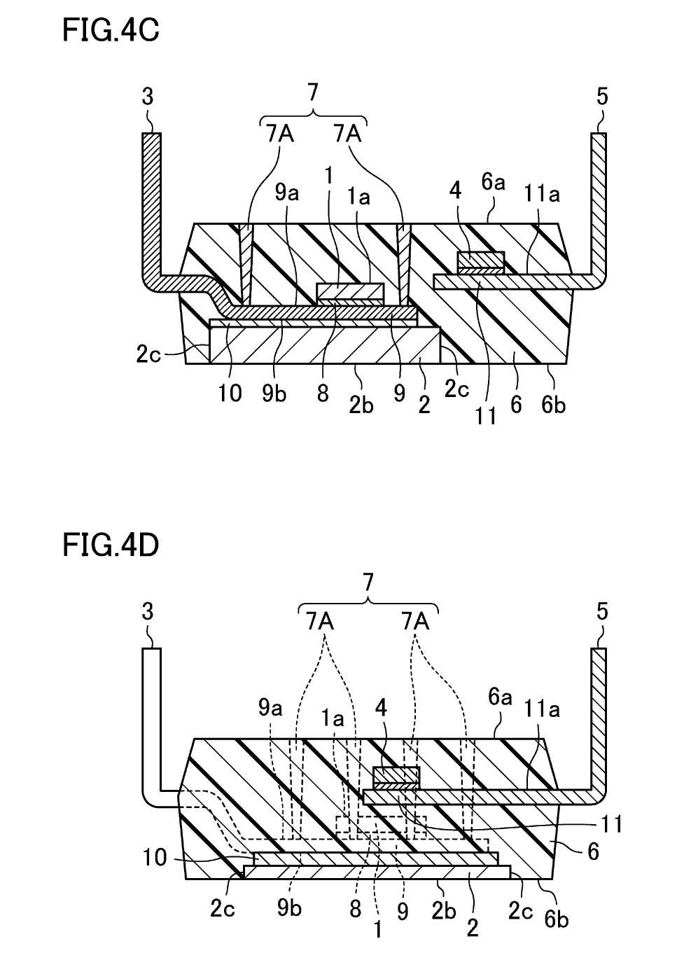

FIG. 1 is a plan view illustrating a semiconductor device according to a first embodiment as viewed from a first surface of a package (or a sealing structure). FIG. 2 is a plan view illustrating the semiconductor of the present embodiment as viewed from a second surface of the package. Each of FIGS. 3A, 3B, 3C, and 3D is a plan view illustrating an inner structure of the semiconductor device of the present embodiment. FIG. 4A is a cross-sectional view taken along the line IVA-IVA in FIG. 3A. FIG. 4B is a cross-sectional view taken along the line IVB-IVB in FIG. 3B. FIG. 4C is a cross-sectional view taken along the line IVC-IVC in FIG. 3C. FIG. 4D is a cross-sectional view taken along the line IVD-IVD in FIG. 3D.

The semiconductor device of the present embodiment includes, as shown in FIGS. 1-4D, a first lead frame 3, a power device 1, a heat sink (or a radiation plate) 2, a control device 4, a second lead frame 5, a package 6, and a noise shield 7 including a plurality of noise shielding poles 7A.

As shown in FIGS. 3A and 4A, the first lead frame 3 is made of a material having good conductivity such as copper (Cu) etc., and includes a first die pad 9, and a plurality of leads. The power device 1 is bonded to a surface 9a (hereinafter referred to as an “upper surface”) of the first die pad 9 of the first lead frame 3 using, for example, brazing filler metal 8. Bonding pads (not shown) of the power device 1 and the leads of the first lead frame 3 are electrically connected through metal members 21. The power device 1 is an insulated gate bipolar transistor (IGBT), a power metal-oxide-semiconductor field-effect transistor (MOSFET), etc. The power device 1 described in this description is a horizontal power MOSFET with a built-in diode. The metal member 21 described in this description is an aluminum (Al) wire, but the aluminum wire may be replaced with metal wire made of gold (Au), copper (Cu), etc., an aluminum (Al) ribbon, a copper (Cu) clip etc. The aluminum ribbon and the copper clip are advantageous because they have a larger cross sectional area and a smaller wiring resistance than the aluminum wire, and can reduce power loss.

The heat sink 2 is fixed to the other surface 9b (hereinafter referred to as a “lower surface”) of the first die pad 9 of the first lead frame 3 with an insulating sheet 10 interposed therebetween. The heat sink 2 may be made of metal having good thermal conductivity, such as copper (Cu), aluminum (Al), etc.

The insulating sheet 10 is made of a thermally conductive insulating material, and effectively transfers heat generated by the power device 1 to the heat sink 2. The insulating sheet 10 may be a three-layer sheet including an insulating layer sandwiched between adhesive layers.

The control device 4 is a device for controlling the power device 1, and includes a drive circuit, an overcurrent protection circuit, etc. The control device 4 is bonded to a surface 11a (hereinafter referred to as an “upper surface”) of a second die pad 11 of the second lead frame 5, for example, using silver (Ag) paste. One or more of bonding pads (not shown) of the control device 4 are electrically connected to a plurality of leads of the second lead frame 5 through gold (Au) wires 22. One or more of the bonding pads of the control device 4 are electrically connected to the bonding pads of the power device 1 (now shown) through the gold wires 22. Thus, the power device 1 can be controlled by the control device 4.

The package 6 is made of, for example, thermosetting resin such as epoxy resin etc., and covers the power device 1, part of the first lead frame 3 including the first die pad 9, the control device 4, part of the second lead frame 5 including the second die pad 11, and side surfaces 2c of the heat sink 2. Thus, the package 6 integrates the first lead frame 3 and the second lead frame 5, and protects the power device 1 and the control device 4.

The heat sink 2 is made of a material having good thermal conductivity such as copper (Cu), aluminum (Al), etc., and a surface 2b (hereinafter referred to as a “lower surface”) of the heat sink 2 is exposed from a second surface 6b (hereinafter referred to as a “lower surface”) of the package 6. Thus, the heat generated by the power device 1 can efficiently be dissipated to the outside. The side surfaces 2c of the heat sink 2 are covered with the package 6, thereby reinforcing bonding between the heat sink 2 and the first lead frame 3.

An end of the first lead frame 3 and an end of the second lead frame 5 protrude from side surfaces of the package 6, respectively, and are connected to a circuit of an inverter control device etc. as mounting terminals of the semiconductor device.

Each of the noise shielding poles 7A constituting the noise shield 7 has a lower end which is in contact with the first die pad 9 of the first lead frame 3, and an upper end which is buried in the package 6 to be exposed in a first surface 6a (hereinafter referred to as an “upper surface”) of the package 6. The upper end of the noise shielding pole 7A has a larger horizontal cross sectional area than a lower end thereof. For example, the noise shielding pole 7A is in the shape of a truncated cone having a diameter gradually increasing from the lower end to the upper end. The noise shield 7 may be a resin mold made of resin mixed with particles of magnetic metal oxide such as chromium oxide, nickel oxide, etc., or with magnetic powder such as ferrite powder etc.

When the noise shield 7 is made of a conductive material, such as a resin mold prepared by mixing epoxy resin etc. and conductive metal such as nickel (Ni) etc., or carbon powder, the noise shield 7 is electrically connected to a ground (GND) terminal of the inverter control device through a GND terminal of the power device 1 electrically connected to the first die pad 9.

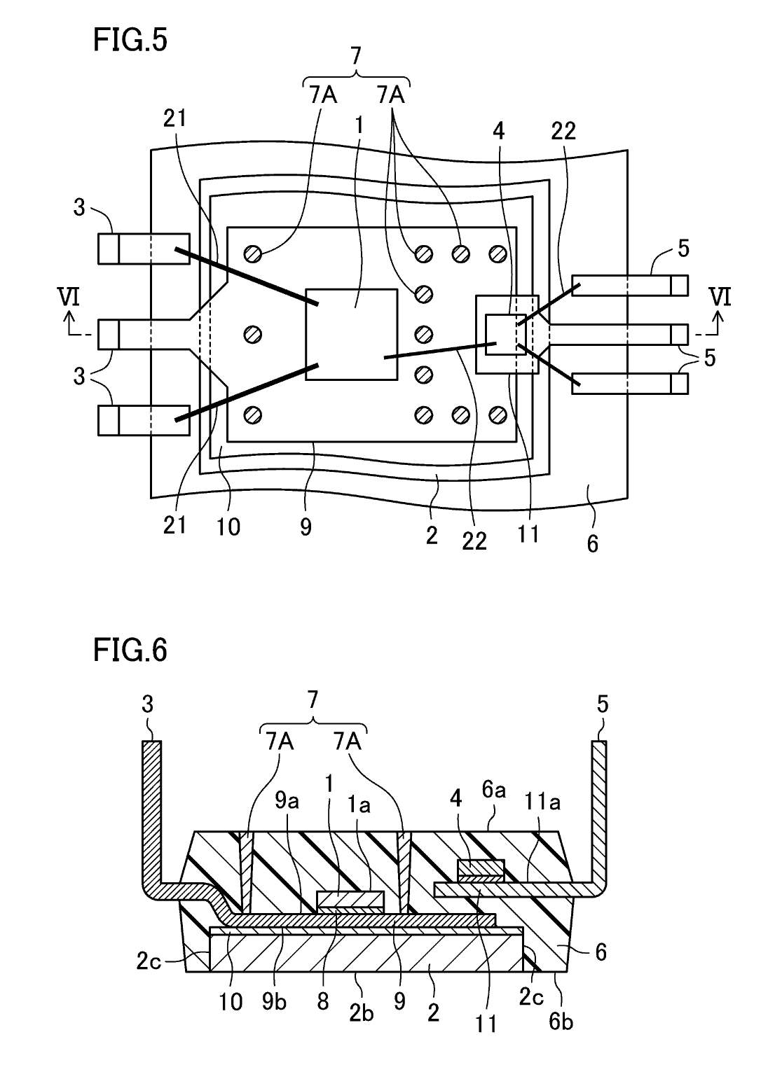

In FIG. 3A, the noise shield 7 includes the plurality of noise shielding poles 7A, and at least some of the noise shielding poles 7A are arranged to form a barrier between the power device 1 and the control device 4. When viewed from a surface 1a (hereinafter referred to as “upper surface”) of the power device 1 as shown in FIG. 3A, the at least some of the noise shielding poles 7A are aligned in line between the power device 1 and the control device 4. However, depending on the size of the first die pad 9, the at least some of the noise shielding poles 7A may be arranged to surround three sides of the second die pad 11 on which the control device 4 is mounted except for a side to which the leads are fixed as shown in FIGS. 5 and 6. In arranging the noise shielding poles 7A to surround the three sides of the second die pad 11, the noise shielding poles 7A are arranged to form a barrier at least between the power device 1 and the control device 4 when viewed from the upper surface 1a of the power device 1. Multiple lines of the noise shielding poles 7A may be formed between the power device 1 and the control device 4. In this embodiment, the plurality of noise shielding poles 7A arranged to form the barrier constitute the noise shield 7. However, a single continuous wall may constitute the noise shield 7.

In the first embodiment, the noise shielding poles 7A constitute the noise shield 7 extending from the upper surface 6a of the package 6 to the upper surface 9a of the first die pad 9, and at least some of the noise shielding poles 7A are arranged at intervals to form the barrier between the power device 1 and the control device 4 when viewed from the upper surface 1a of the power device 1. Thus, electromagnetic wave noise generated by the power device 1 is partially absorbed by the noise shield 7. When the noise shield 7 is conductive, the electromagnetic wave noise flows to the first die pad 9 through the noise shield 7. This can reduce the electromagnetic wave noise which reaches the control device 4, thereby preventing malfunction of the control device 4, and improving reliability. In this embodiment, the noise shielding poles 7A are formed opposite the control device 4 relative to the power device 1. However, the noise shielding poles 7A may not be formed opposite the control device 4 relative to the power device 1.

To reduce the electromagnetic wave noise which reaches the control device 4, each of the noise shielding poles 7A preferably has a larger cross sectional area from the bottom side to the upper side in the vertical direction. An area of part of the noise shielding pole 7A connected to the first die pad 9 (the lower end) is restricted by the size of the power device 1 mounted on the first die pad 9. Thus, when the noise shielding pole 7A is in the shape of a circular cylinder, the cross sectional area of the noise shielding pole 7A cannot be easily increased in the vertical direction. In the present embodiment, however, the noise shielding pole 7A is in the shape of a truncated cone, i.e., its diameter gradually increases from the first die pad 9 to the upper surface 6a of the package 6. Therefore, as compared with the circular cylindrical noise shielding pole 7A, the cross sectional area of the noise shielding pole 7A can be increased from the bottom side to the upper side in the vertical direction. This can reduce the electromagnetic wave noise which is generated by the power device 1, and reaches the control device 4, thereby preventing the malfunction of the control device 4 more effectively.

The noise shield 7 has higher thermal conductivity than the package 6. Thus, heat generated by the power device 1 can efficiently be dissipated from the upper end of the noise shield 7 exposed in the upper surface 6a of the package 6. Therefore, adverse effect of the heat generated by the power device 1 on the control device 4 can be reduced.

As shown in FIGS. 3B and 4B, a cross-sectional area of the noise shielding pole 7A is different from one another. That is, a cross-sectional area of the first noise shielding pole is larger than the second noise shielding pole. The wire 22 passes between the first noise shielding pole and the second noise shielding pole.

As shown in FIG. 3C, a shape of the noise shielding pole 7A in plan view is not limited to a circular form. It can be a oval form.

As shown in FIG. 3D, two first lead frames 3 and two first die pads 9 are disposed in the sealing structure, and the first semiconductor chip (for example, power device) 1 is disposed on the first die pad 9, respectively. As shown in FIG. 4D, the noise shielding structure 7 is disposed between the first semiconductor chip (for example, power device) 1 and the second semiconductor chip (for example, control device) 4. It is noted that the noise shielding structure 7 is not limited to the structure penetrating from the top surface of the sealing structure 6 to the top surface of the first lead frame 3. That is, the first semiconductor chip 1 and the second semiconductor chip 4 are overlapping with each other in plan view, and the noise shielding structure 7 is disposed between the first semiconductor chip 1 and the second semiconductor chip 4. In this structure, the noise shielding structure 7 penetrates or not from the first side surface of the sealing structure 6 to the second side surface of the sealing structure 6, the first side surface being opposite to the second side surface.

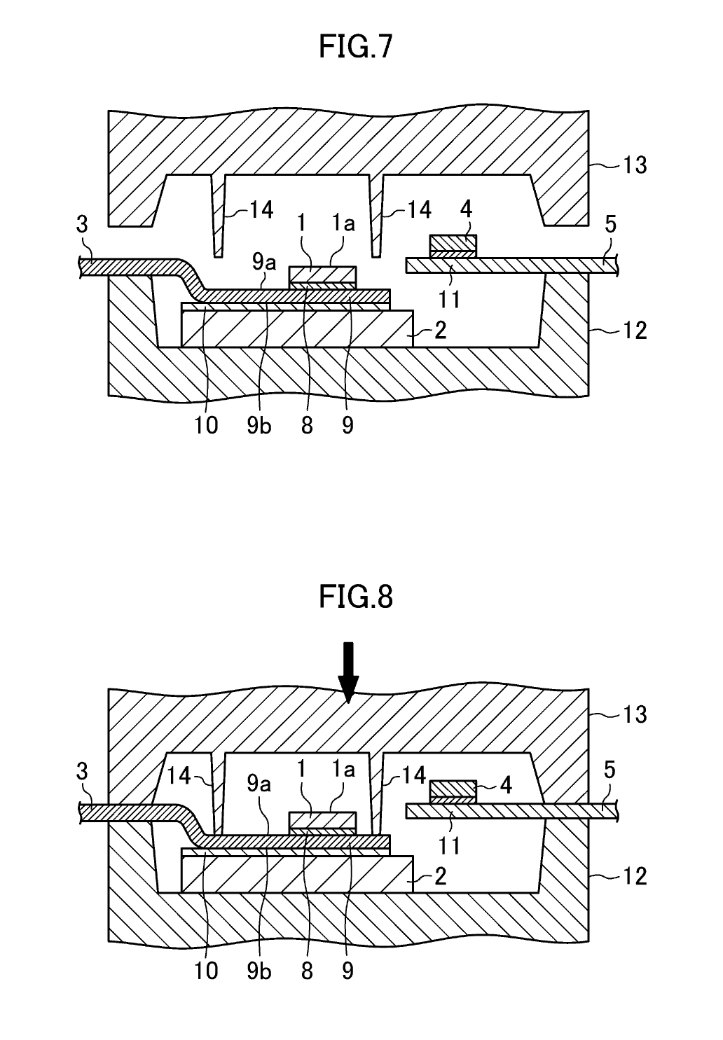

A method for manufacturing the semiconductor device of the present embodiment will be described with reference to FIGS. 7-11. As shown in FIG. 7, the heat sink 2 to which the insulating sheet 10 is temporarily adhered is placed in a cavity of a lower mold 12 with a surface of the heat sink 2 opposite the insulating sheet 10 facing down. Then, the first lead frame 3 and the second lead frame 5 are placed at predetermined positions in the lower mold 12, respectively, with the lower surface 9b of the first die pad 9 of the first lead frame 3 in contact with the insulating sheet 10.

Then, as shown in FIG. 8, an upper mold 13 is moved down to cramp the first and second lead frames 3 and 5 between the upper and lower molds 13 and 12. The upper mold 13 has a plurality of insert pins 14 formed to be positioned above the first die pad 9 of the first lead frame 3. When the first and second lead frames 3 and 5 are cramped between the upper and lower molds 13 and 12, the insert pins 14 press the first die pad 9 of the first lead frame 3 downward. Thus, the heat sink 2 adhered to the lower surface 9b of the first die pad 9 of the first lead frame 3 is pressed onto the lower mold 12.

At least one of the plurality of insert pins 14 is positioned between the power device 1 and the control device 4 when viewed from the upper surface 1a of the power device 1. The at least one insert pin 14 positioned between the power device 1 and the control device 4 is in the shape of a truncated cone having a diameter gradually increasing upward from a surface thereof in contact with the first die pad 9 of the first lead frame 3. The insert pin 14 may be in the shape of a truncated pyramid.

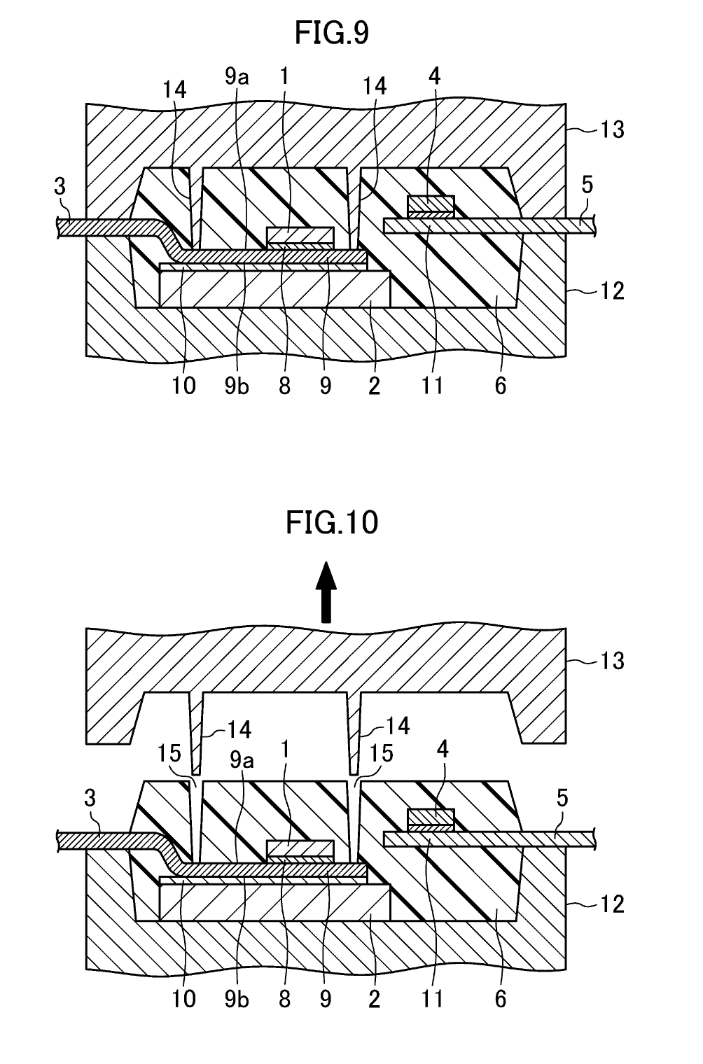

Then, as shown in FIG. 9, sealing resin such as epoxy resin etc. is injected between the upper and lower molds 13 and 12 by transfer molding to form a package 6 which covers the power device 1, the control device 4, and side surfaces of the heat sink 2. Since the heat sink 2 is pressed onto the lower mold 12 by the insert pins 14, the sealing resin does not flow onto the lower surface 2b of the heat sink 2. Thus, the lower surface 2b of the heat sink 2 is not covered with the sealing resin, and heat can effectively be dissipated from the lower surface 2b of the heat sink 2 to the outside.

Since the insert pins 14 press the upper surface 9a of the first die pad 9, tip ends of the insert pins 14 slightly bite into the upper surface 9a of the first die pad 9. Thus, the sealing resin does not flow onto the surface of the first die pad 9 in contact with the insert pins 14.

In sealing the resin, an adhesive layer (not shown) of the insulating sheet 10 arranged between the first die pad 9 of the first lead frame 3 and the heat sink 2 is molten by heat transferred from the lower and upper molds 12 and 13, and is cured. Thus, the insulating sheet 10, the lower surface 9b of the first die pad 9 of the first lead frame 3, and the heat sink 2 are securely adhered.

When the upper mold 13 is moved up as shown in FIG. 10, openings 15 corresponding to the insert pins 14 are formed in the package 6. Each of the openings 15 is in the shape of a truncated cone having a diameter gradually increasing upward from the first die pad 9 of the first lead frame 3. The sealing resin is not adhered to the surfaces of the first die pad 9 exposed from the openings 15, and the first die pad 9 of the first lead frame 3 is exposed in the openings 15.

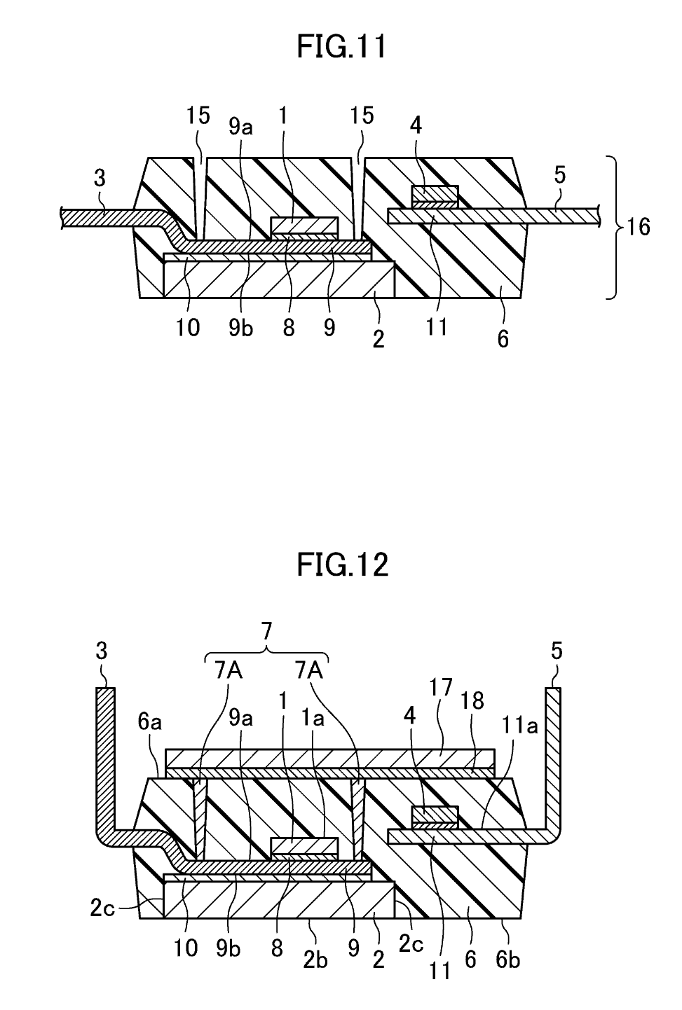

As shown in FIG. 11, a sealed product 16 is removed from the lower mold 12. Then, magnetic paste containing particles of magnetic metal such as nickel (Ni) etc., epoxy resin, a solvent, etc., is injected into the openings 15 by printing such as screen printing, or by dispensing. Then, the magnetic paste is cured to form the noise shielding poles 7A constituting the noise shield 7 in the openings 15. Since the insert pins 14 press the upper surface 9a of the first die pad 9 in the sealing process, the surfaces of the first die pad 9 exposed from the openings 15 are recessed. Thus, tip ends of the noise shielding poles 7A slightly bite into the upper surface 9a of the first die pad 9, thereby reinforcing mechanical bonding between lower surfaces of the noise shielding poles 7A and the upper surface 9a of the first die pad 9.

When the noise shield 7 is conductive, electrical bonding between the noise shield 7 and the upper surface 9a of the first die pad 9 is also reinforced. Thus, electromagnetic wave noise generated by the power device 1 can flow to the first die pad 9 through the noise shield 7, thereby effectively reducing the electromagnetic wave noise.

When the magnetic paste has high viscosity, the applied magnetic paste may be thermally cured after degassing under vacuum, or may be thermally cured in a vacuum oven to prevent voids in the openings 15. Thus, the noise shield 7 can be formed uniformly.

In the first embodiment, the two separate lead frames have been used. However, for example, a single lead frame prepared by integrating the first and second lead frames 3 and 5 may be used. This can provide the semiconductor device with improved productivity and alignment accuracy.

In the first embodiment described above, the noise shield 7 extending from the upper surface 6a of the package 6 to the upper surface 9a of the first die pad 9 of the first lead frame 3 is provided at least between the power device 1 and the control device 4. Thus, the electromagnetic wave noise generated from the power device 1 is partially absorbed by the noise shield 7. When the noise shield 7 is conductive, the electromagnetic wave noise flows to the first die pad 9 through the noise shield 7. This can reduce the electromagnetic wave noise which reaches the control device 4, thereby preventing malfunction of the control device 4, and improving reliability.

### Second Embodiment

FIG. 12 is a cross-sectional view illustrating a semiconductor device according to a second embodiment. As shown in FIG. 12, the semiconductor device of the second embodiment is the same as the semiconductor device of the first embodiment except that an electromagnetic wave absorber plate 17 is provided on a surface of the package 6 opposite the heat sink 2 (the upper surface 6a). The electromagnetic wave absorber plate 17 may be, for example, a copper (Cu) plate plated with a magnetic material such as Ni etc., or a magnetic plate made of a conductive metal plate of a Ni—Fe alloy such as a 42 alloy, and a magnetic material such as ferrite.

A method for manufacturing the semiconductor device of the present embodiment will be described below. A semiconductor device including the noise shield 7 is formed in the same manner as the first embodiment. Then, an adhesive 18 such as epoxy resin etc. is applied to the upper surface 6a of the package 6, and the electromagnetic wave absorber plate 17 is placed on the adhesive 18. In this state, the adhesive 18 is thermally cured to provide the semiconductor device with the electromagnetic wave absorber plate 17. In place of the adhesive 18, an insulating sheet may be adhered to the upper surface 6a of the package 6, and may be thermally cured after the electromagnetic wave absorber plate 17 is placed thereon.

The noise shielding poles 7A constituting the noise shield 7 are formed by thermally curing magnetic paste containing particles of magnetic metal such as nickel, epoxy resin, a solvent, etc. Thus, an upper surface of each of the noise shielding poles 7A is recessed from the upper surface 6a of the package 6 because the magnetic paste shrinks to cure. Therefore, as shown in FIG. 11, the electromagnetic wave absorber plate 17 on the upper surface 6a of the package 6 is not lifted up by the upper surfaces of the noise shielding poles 7A. As a result, the upper surface 6a of the package 6 is kept flat, and the entire area of the electromagnetic wave absorber plate 17 can be adhered thereto without reducing adhesive strength therebetween.

According to the second embodiment, the added electromagnetic wave absorber plate 17 can block not only the electromagnetic wave noise from the power device 1, but also the electromagnetic wave noise coming down to the semiconductor device from outside. This can provide the semiconductor device with improved operational reliability.

### Third Embodiment

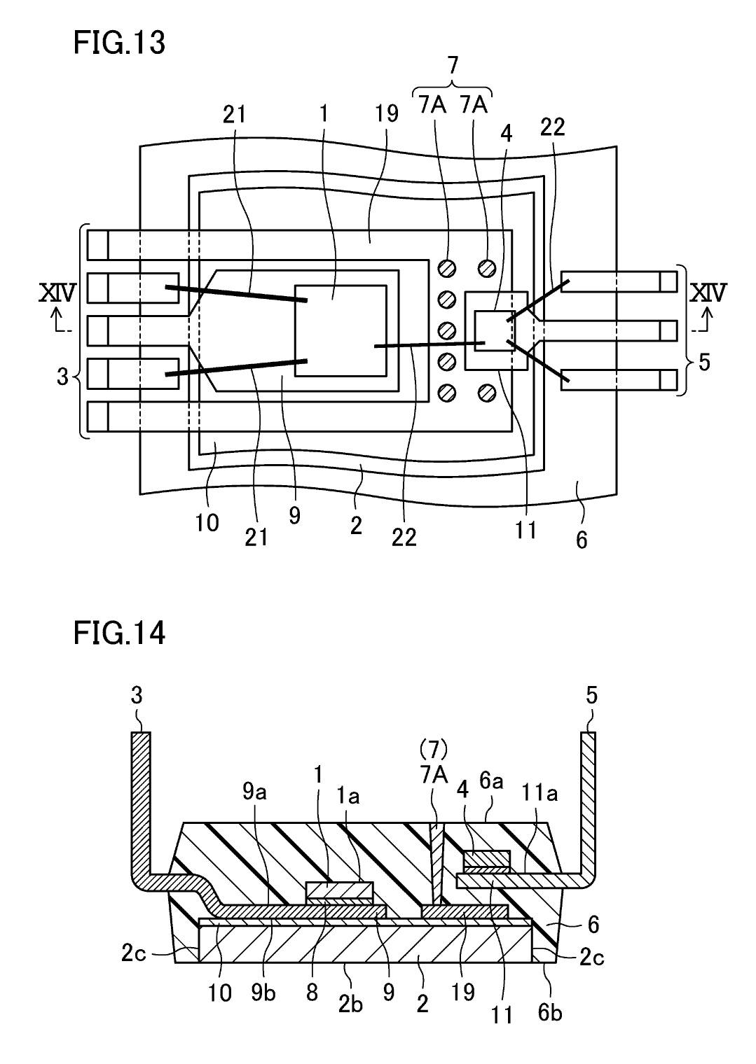

FIGS. 13 and 14 show a plan view and a cross-sectional view both illustrating a semiconductor device according to a third embodiment. As shown in FIGS. 13 and 14, the semiconductor device of the third embodiment is the same as the semiconductor device of the first embodiment except that the noise shield 7 is formed on a ground (GND) portion 19. The GND portion 19 is in the shape of a rectangle, for example, and is electrically isolated from the first die pad 9 of the first lead frame 3. The GND portion 19 is provided on an upper surface of the heat sink 2 with the insulating sheet 10 interposed therebetween.

A vertical power MOSFET uses a back surface of a chip as a drain electrode. Thus, large current flows from the power device 1 to a drain terminal of the semiconductor device through the first die pad 9. Therefore, when the semiconductor device includes the conductive noise shield 7, the noise shield 7 cannot directly be bonded to the first die pad 9. However, the power device 1 can be used as the vertical power MOSFET by employing the configuration of the present embodiment.

When viewed from the upper surface 1a of the power device 1, the noise shield 7 extending vertically from the upper surface 6a of the package 6 to the GND portion 19 is provided at least between the power device 1 and the control device 4. Thus, a lower end of the noise shield 7 can mechanically and electrically be connected to the GND portion 19.

In the semiconductor device of the present embodiment, a power device using a back surface of a chip as a drain electrode can be used. Thus, the semiconductor device can be provided with good versatility.

In the present embodiment, the electromagnetic wave noise generated from the power device 1 partially flows to the GND portion 19 through the noise shield 7. Thus, the electromagnetic wave noise which reaches the control device 4 can be reduced, thereby preventing malfunction of the control device 4, and improving reliability.

The electromagnetic wave absorber plate (or a radiation absorbing plate) 17 of the second embodiment may be provided on the upper surface 6a of the package 6 of the semiconductor device of the present embodiment.

### Fourth Embodiment

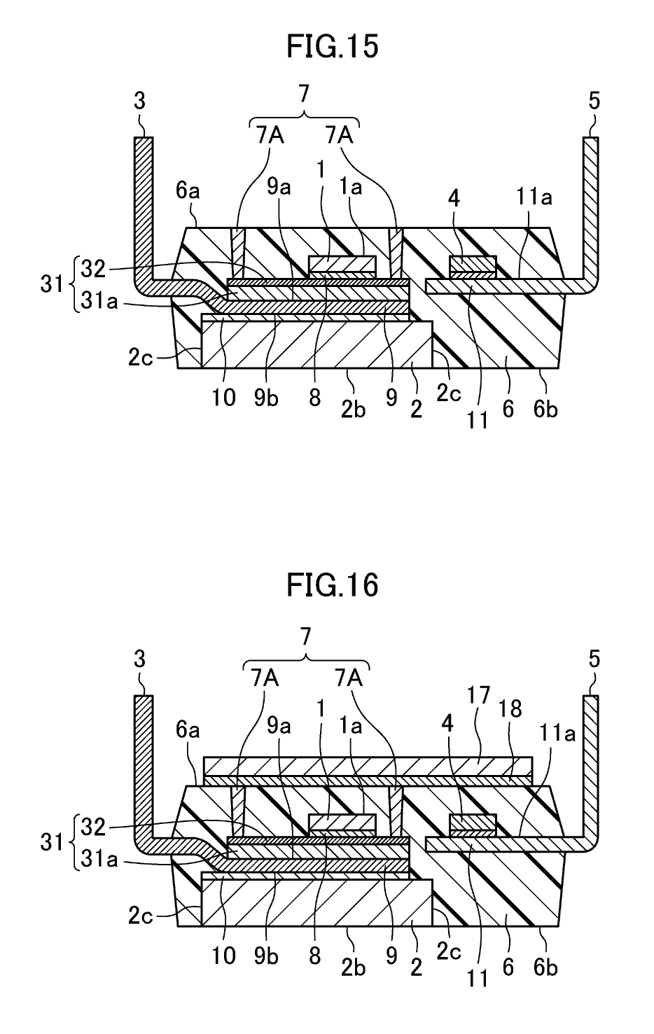

FIG. 15 is a cross-sectional view illustrating a semiconductor device of a fourth embodiment. As shown in FIG. 15, the semiconductor device of the fourth embodiment is the same as the semiconductor device of the first embodiment except that a circuit board 31 is provided. The circuit board 31 is mounted on the upper surface 9a of the first die pad 9 included in the first lead frame 3. One or more power devices 1 are mounted on a circuit pattern 32 formed on a surface 31a (hereinafter referred to as an “upper surface”) of the circuit board 31. The noise shield 7 is formed to extend vertically relative to the upper surface 1a of the power device 1 from the upper surface 6a of the package 6 to the circuit pattern 32.

With this configuration, the power device 1 and the control device 4 are electrically connected through the circuit pattern 32. When the power device 1 includes, for example, a plurality of devices such as an IGBT and a diode, these devices can electrically be connected through the circuit pattern 32. This can provide the semiconductor device with good design flexibility and versatility.

The noise shield 7 is formed at least between the power device 1 and the control device 4 in a direction parallel to the upper surface 1a of the power device 1 to extend vertically from the upper surface 6a of the package 6 to the upper surface of the circuit pattern 32 of the circuit board 31. Thus, a lower end of the noise shield 7 is electrically connected to the first lead frame 3 through via holes (not shown) formed in a GND portion of the circuit pattern 32 or the circuit board 31.

The semiconductor device of the fourth embodiment includes the circuit board 31. Thus, the power device 1 and the control device 4 can easily be connected. A power device formed with a plurality of devices can be mounted on the circuit board 31. This can easily provide the semiconductor device with good design flexibility and versatility.

In the semiconductor device of the present embodiment, even when the noise shield 7 is conductive, the electromagnetic wave noise generated from the power device 1 partially flows through the noise shield 7 to the GND portion of the circuit board 31, or to the first die pad 9 of the first lead frame 3. This can reduce the electromagnetic wave noise which reaches the control device 4, thereby preventing malfunction of the control device 4, and improving reliability.

As shown in FIG. 16, the electromagnetic wave absorber plate 17 of the second embodiment may be provided on the upper surface 6a of the package 6 of the present embodiment.

In each of the embodiments, the power device is mounted on the first lead frame, and the control device is mounted on the second lead frame. However, the present disclosure is not limited to the combination of the power device and the control device, and can advantageously be applied to semiconductor devices in which a plurality of semiconductor devices are sealed in a single package. The plurality of noise shielding poles 7A constituting the noise shield 7 may be integrated.

The present disclosure can improve operational reliability of the semiconductor devices, and is particularly useful for semiconductor devices such as insulated gate bipolar semiconductor modules, intelligent power modules, etc.

What is claimed is:

1. A semiconductor device comprising:
a first lead frame including a first die pad;
a second lead frame including a second die pad;
a first semiconductor chip disposed on the first die pad;
a second semiconductor chip disposed on the second die pad;
a sealing structure which covers the first semiconductor chip and the second semiconductor chip; and
a noise shield disposed between the first semiconductor chip and the second semiconductor chip.

2. The semiconductor device of claim 1, wherein
the first semiconductor chip is disposed on a first surface of the first lead frame, and
a bottom portion of the noise shield is in contact with the first surface of the first lead frame.

3. The semiconductor device of claim 2, wherein
a top portion of the noise shield is in contact with a surface of the sealing structure.

4. The semiconductor device of claim 1, wherein
the noise shield comprises a plurality of noise shielding poles, and
the plurality of noise shielding poles are adjacent to one another and disposed between the first semiconductor chip and the second semiconductor chip.

5. The semiconductor device of claim 4, wherein
the plurality of noise shielding poles contact a first surface of the first lead frame, and
the first semiconductor chip is disposed on the first surface of the first lead frame.

6. The semiconductor device of claim 5, wherein
top end portions of the plurality of noise shielding poles are in contact with a surface of the sealing structure.

7. The semiconductor device of claim 5, wherein
said plurality of noise shielding poles extend from the first surface of the first lead frame to an upper surface of the sealing structure.

8. The semiconductor device of claim 1, wherein
a bottom end portion of the noise shield is in contact with the first die pad.

9. The semiconductor device of claim 8, wherein
the first die pad has a recess, and the bottom end portion of the noise shield is disposed in the recess.

10. The semiconductor device of claim 1, wherein
the first lead frame comprises a ground portion which provides a ground voltage, and the noise shield is electrically connected to the ground portion.

11. The semiconductor device of claim 10, wherein
the ground portion has a recess, and a bottom end portion of the noise shield is disposed in the recess.

12. The semiconductor device of claim 1, further comprising:
a circuit board on the first die pad, wherein
the first semiconductor chip is disposed on the circuit board.

13. The semiconductor device of claim 1, further comprising:
a radiation plate, wherein
the first semiconductor chip is disposed on a first surface of the first lead frame, and
the radiation plate is disposed on a second surface of the first lead frame, the second surface being opposite to the first surface.

14. The semiconductor device of claim 2, wherein
the radiation plate comprises a third surface and a fourth surface, the third surface being opposite to the fourth surface,
the third surface of the radiation plate is in contact with the second surface of the first lead frame, and
the fourth surface of the radiation plate is in contact with a surface of the sealing structure.

15. The semiconductor device of claim 1, wherein
the noise shield includes a magnetic material.

16. The semiconductor device of claim 1, wherein
a bottom end portion of the noise shield faces a first surface of the first lead frame, and
a cross-sectional area of the bottom end portion parallel to the first surface of the first lead frame is smaller than a cross-sectional area of a top end portion parallel to the first surface of the first lead frame.

17. The semiconductor device of claim 1, wherein
the noise shield comprises a plurality of noise shielding poles, and
the plurality of noise shielding poles surround the second die pad.

18. The semiconductor device of claim 17, wherein
the plurality of noise shielding poles contact a first surface of the first lead frame, and
the first semiconductor chip is disposed on the first surface of the first lead frame.

19. The semiconductor device of claim 18, wherein
top end portions of the plurality of noise shielding poles are in contact with a surface of the sealing structure.

20. The semiconductor device of claim 1, wherein
the noise shield comprises a plurality of noise shielding poles, and
the plurality of noise shielding poles are adjacent to the periphery of the second die pad.

21. The semiconductor device of claim 20, wherein
the plurality of noise shielding poles contact a first surface of the first lead frame, and
the first semiconductor chip is disposed on the first surface of the first lead frame.

22. The semiconductor device of claim 21, wherein
top end portions of the plurality of noise shielding poles are in contact with a surface of the sealing structure.

23. The semiconductor device of claim 1, further comprising:
a radiation absorbing plate disposed on a surface of the sealing structure.

24. The semiconductor device of claim 1, wherein
the first semiconductor chip is a power device, and the second semiconductor chip is a control device.

25. The semiconductor device of claim 1, wherein
the noise shield comprises a first noise shielding portion and a second noise shielding portion, and the first noise shielding portion is separated from the second noise shielding portion.

26. The semiconductor device of claim 25, further comprising:
a wire which electrically connects the first semiconductor chip and the second semiconductor chip, wherein
the wire passes between the first noise shielding portion and the second noise shielding portion.

27. The semiconductor device of claim 1, wherein
the first lead frame and the second lead frame overlap with each other in plan view.

28. The semiconductor device of claim 1, further comprising:
a radiation plate, wherein
the first semiconductor chip is disposed on a first surface of the first lead frame,
the radiation plate is disposed on a second surface of the first lead frame, the second surface being opposite to the first surface, and
the radiation plate and the second lead frame overlap with each other in plan view.

29. The semiconductor device of claim 1, wherein
the first lead frame comprises a ground portion which provides a ground voltage,
the noise shield is electrically connected to the ground portion,
the ground portion includes a covered portion and an external portion,
the covered portion is covered by the sealing structure, and
the external portion is outside of the sealing structure.

30. The semiconductor device of claim 1, wherein
the first lead frame comprises a ground portion which provides a ground voltage,
the noise shield is electrically connected to the ground portion, and
the ground portion and the second lead frame overlap with each other in plan view.

31. The semiconductor device of claim 1, wherein
the noise shield comprises a first noise shielding portion and a second noise shielding portion,
the first noise shielding portion is separated from the second noise shielding portion, and
a cross-sectional area of the first noise shielding portion is larger than a cross-sectional area of the second noise shielding portion in plan view parallel to a surface of the first lead frame.

32. The semiconductor device of claim 31, further comprising:
a wire which electrically connects the first semiconductor chip and the second semiconductor chip, wherein
the wire passes between the first noise shielding portion and the second noise shielding portion.

33. The semiconductor device of claim 1, wherein
the noise shield comprises a first noise shielding pole and a second noise shielding pole,
the first noise shielding pole is separated from the second noise shielding pole, and
a diameter of the first noise shielding portion is larger than a diameter of the second noise shielding portion in plan view parallel to a surface of the first lead frame.

34. The semiconductor device of claim 33, further comprising:
a wire which electrically connects the first semiconductor chip and the second semiconductor chip, wherein
the wire passes between the first noise shielding pole and the second noise shielding pole.

35. The semiconductor device of claim 1, further comprising:
a third lead frame including a third die pad; and
a third semiconductor chip disposed on the third die pad, wherein
the noise shield comprises a plurality of first noise shielding portions in contact with the first lead frame and a plurality of third noise shielding portions in contact with the third lead frame.

36. The semiconductor device of claim 35, wherein
the first lead frame and the second lead frame overlap with each other in plan view, and
the second lead frame and the third lead frame overlap with each other in plane view.

37. The semiconductor device of claim 1, wherein
the first semiconductor chip and the second chip overlap with each other in plan view.
